(19) United States
(12) Patent Application Publication
(10) Pub. No.: US 2024/0339365 A1
(43) Pub. Date: Oct. 10, 2024

(54) RESILIENT CONDUCTIVE BUMP FOR MICROELECTRONIC TESTING

(71) Applicant: BAE SYSTEMS Information and Electronic Systems Integration Inc., Nashua, NH (US)

(72) Inventors: Nathaniel P. Wyckoff, Marion, IA (US); Jacob R. Mauermann, Marion, IA (US); Mark E. Whiting, Coralville, IA (US)

(73) Assignee: BAE SYSTEMS Information and Electronic Systems Integration Inc., Nashua, NH (US)

(21) Appl. No.: 18/297,798

(22) Filed: Apr. 10, 2023

(51) Int. Cl. H01L 21/66; G01R 1/067

(52) U.S. Cl. CPC H01L 22/30; G01R 1/067

(57) ABSTRACT

A microelectronic component includes a substrate having at least one electrical pad, a resilient material on the substrate, and a conductive element on or in the resilient material and coupled to the at least one conductive pad. The resilient material may include, for instance, a compressible polymer. The conductive elements configured to be placed in contact with at least one test probe, where the resilient material is configured to be compressed by the at least one electrical probe into a deformed shape and where the resilient material is configured to return from the deformed shape to a non-deformed shape subsequent to a removal of the conductive element from contact with the at least one electrical probe.

### FIELD OF DISCLOSURE

The present disclosure relates to microelectronics, and more particularly, to resilient conductive bumps for probing microelectronic devices.

### BACKGROUND

Microelectronic components are devices typically made from semiconductor materials and fabricated as integrated circuits. Some post-fabrication activities, such as testing and quality control, involve establishing electrical contacts with the components. For example, electrical probing of microelectronic components can involve physically contacting input/output (I/O) connections and power/ground pads with a needle, whisker, pogo, or membrane style probe. The density and total number of such probes may be limited for individually micro-positioned probes. Higher probe densities can be achieved using component-specific solutions such as cantilever, micro wire, and buckling beam.

### BRIEF DESCRIPTION OF THE DRAWINGS

FIGS. 1A and 1B are side cross-sectional views of a microelectronic component with a resilient conductive bump in an undeformed shape and a deformed shape, respectively, in accordance with an example of the present disclosure.

FIGS. 2 and 3 are side cross-sectional views of the microelectronic component of FIG. 1, in accordance with examples of the present disclosure.

FIG. 4 is a side cross-sectional view of a microelectronic component having multiple bumps along a surface of a substrate, in accordance with an example of the present disclosure.

FIG. 5 is a side cross-sectional view of a microelectronic component having multiple bumps along multiple surfaces of a substrate, in accordance with an example of the present disclosure.

FIG. 6 is a block diagram showing a use case for a microelectronic component, in accordance with an example of the present disclosure.

FIG. 7 is side cross-sectional view of a microelectronic component fabrication process using deposition, in accordance with an example of the present disclosure.

FIG. 8 is side cross-sectional view of a microelectronic component fabrication process using screening, in accordance with an example of the present disclosure.

FIG. 9 is side cross-sectional view of a microelectronic component fabrication process using microlithography, in accordance with an example of the present disclosure.

FIG. 10 is a flow diagram of an example methodology for testing a microelectronic component, in accordance with an example of the present disclosure.

FIG. 11 is a flow diagram of an example methodology for fabricating a microelectronic component, in accordance with an example of the present disclosure.

Although the following detailed description will proceed with reference being made to illustrative examples, many alternatives, modifications, and variations thereof will be apparent in light of this disclosure.

### DETAILED DESCRIPTION

Resilient conductive bumps for probing microelectronic devices are described. In an example, a microelectronic component includes a substrate having at least one conductive pad, a resilient material on the substrate, and a conductive element on or in the resilient material and coupled to the at least one conductive pad. The resilient material may include, for instance, a compressible polymer. The conductive element is accessible to at least one electrical test probe, and the resilient material compresses into a deformed shape in response to test probe contact with the conductive element. The resilient material is configured to return from the deformed shape to an undeformed or otherwise regular shape in response to withdrawal of the test probe contact from the conductive element. In some examples, the conductive element, such as silver flake, in included in the such that the bump itself is conductive. In some other examples, the conductive element includes a metalized layer on the bump.

### Overview

As noted above, testing of microelectronic components typically involves physically contacting I/O and power/ground pads of the components with an electrical probe. Probe design is a limiting factor. For example, micro-positioned probes can be individually positioned for a testing a variety of different components, but the density and total number of probes may be limited. Higher probe densities can be achieved with certain component-specific solutions, such as cantilever, micro wire, and buckling beam; however, such solutions may have limited uses and are relatively expensive to build. Furthermore, depending on the probe design and pad size, damage to the components can occur at the pad or other metalized surface during testing, such as when the probe is off center, which leads to defects that impact the yield of the manufacturing process. Therefore, there is a need for improved microelectronic component testing techniques.

An example of the present disclosure provides compressible conductive bumps that can be, for example, additively fabricated directly on a package substrate, printed circuit board, or other substrate. Each bump includes a resilient material that is either covered with a metalized layer or includes a conductive element and is designed to be placed in electrical contact with a probe. Upon contact, the probe deforms the original shape of the bump, and upon removal of the probe, the bump returns from the deformed shape to the original shape or at least to a shape having a lesser degree of deformity. In the case of flip chip probing, the bumps can be the same size and pitch as the solder bumps, which permits testing on a golden unit or multiple test units. A technical advantage with additively produced conductive bumps is that the compressible material used within the bump can be formulated for the specific probing application. For example, for die that have fragile thin films, the bumps can be formulated to have a very low elastic modulus and ensure no damage to the pads during probing. For die with pads that are more prone to oxidation (as might occur on aluminum or copper), the bumps can utilize a higher modulus polymer and/or diamond filler to ensure they can scrub through the metal oxide on the pad and get low contact resistance, while still minimizing pad damage.

### Resilient Conductive Bump Structure

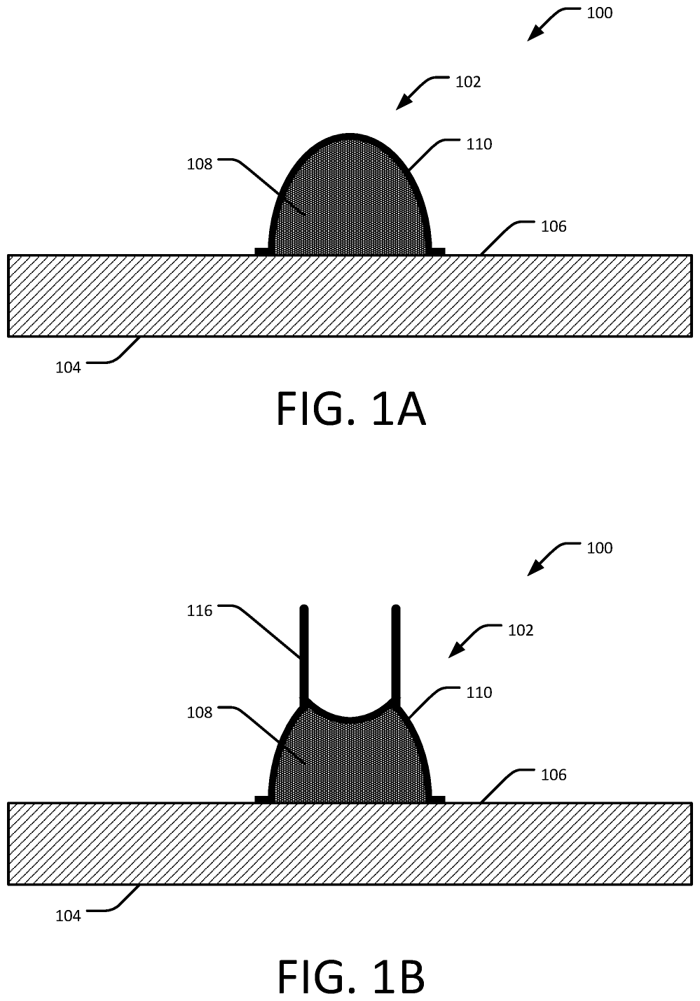

FIGS. 1A and 1B are side cross-sectional views of a microelectronic component 100 with a resilient conductive bump 102, in accordance with an example of the present disclosure. The microelectronic component 100 includes a substrate 104. It will be appreciated that the substrate 104 can include a printed circuit board or other material for supporting electronic components, such as silicon, glass, copper laminate, or a similar substrate card. The bump 102 is attached to, or otherwise mounted on or adjacent to, a surface 106 of the substrate 104. The bump 102 includes a resilient material 108 covered by or integrated with a metalized layer or other electrically conductive element 110. It will be understood that in some examples the resilient material 108 includes an electrically conductive element, such as silver flake, such that the bump 102 itself is conductive. The resilient material 108 can include, for example, a compressible polymer which is time/pressure dispensed, screened, or printed using microlithography to form a dome or other shape with positive curvature. Examples of the compressible polymer include room temperature vulcanizing (RTV) silicone, polyethylene (low density or high density), polypropylene, polyvinyl chloride, polystyrene, polyacrylonitrile, polytetrafluoroethylene, polymethyl methacrylate, polyvinyl acetate, cis-polyisoprene, polychloroprene, polychlorotrifluoroethylene, or a similar material. It will be appreciated that, in some examples, the resilient material 108 can include other types of materials, such as rubber, brass, or other materials that absorb kinetic energy when elastically deformed, and release kinetic energy upon unloading. For instance, the resilient material 108 can be configured to deform (bend) up to approximately 20% from an undeformed state without incurring permanent deformation. More generally, the resilient material 108 can include any material that can resist an energy load where the material does not undergo permanent deformation (or significant permanent deformation), such as a material having high yield stress and a low modulus of elasticity. The conductive element 110 can obtain approximately the same shape (e.g., a dome shape) as the resilient material 108.

FIG. 1A shows the bump 102 in an undeformed shape, such as a dome shape, although it will be understood that the bump 102 can have other shapes. FIG. 1B shows the bump 102 in a deformed shape. The resilient material 108 and the conductive element 110 are deformable. The conductive element 110 can be placed in electrical contact with a probe 116 or another mechanical device, such as shown in FIG. 1B. For example, the conductive element 110 can be vapor deposited (e.g., physical vapor deposition, chemical vapor deposition) or printed on the bump 102 (e.g., at least one conductive trace printed on the bump) using an aerosol jet and can include a robust noble metal such as platinum. In some examples, the conductive element 110 is relatively conformal (e.g., largest thickness of conductive element 110 is no more than 5% different from the smallest thickness of conductive element 110) can deform up to approximately 20% with little to no permanent deformation or damage occurring. In other examples, the thickness of the conductive element 110 is sufficiently small enough so as to permit the conductive element 110 to deform with little to no permanent deformation or damage occurring.

### Resilient Conductive Bump Configurations

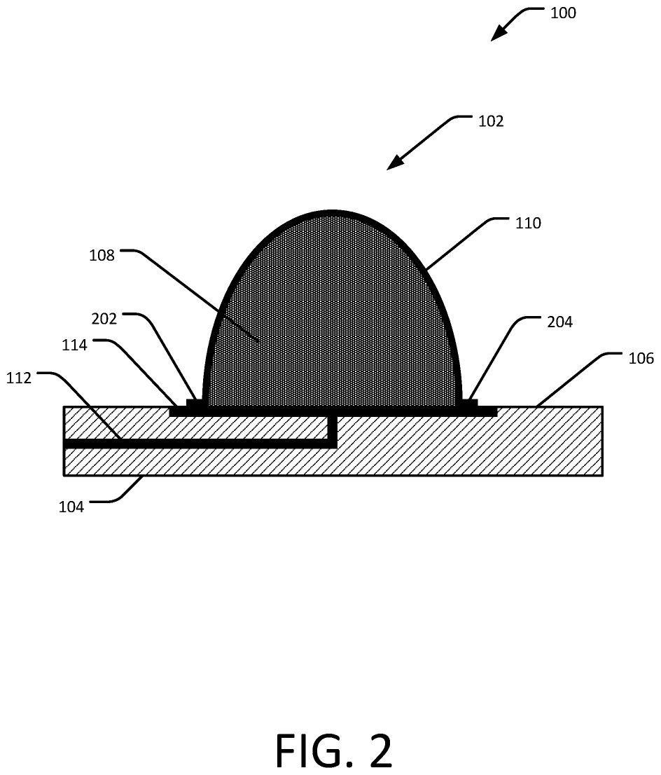

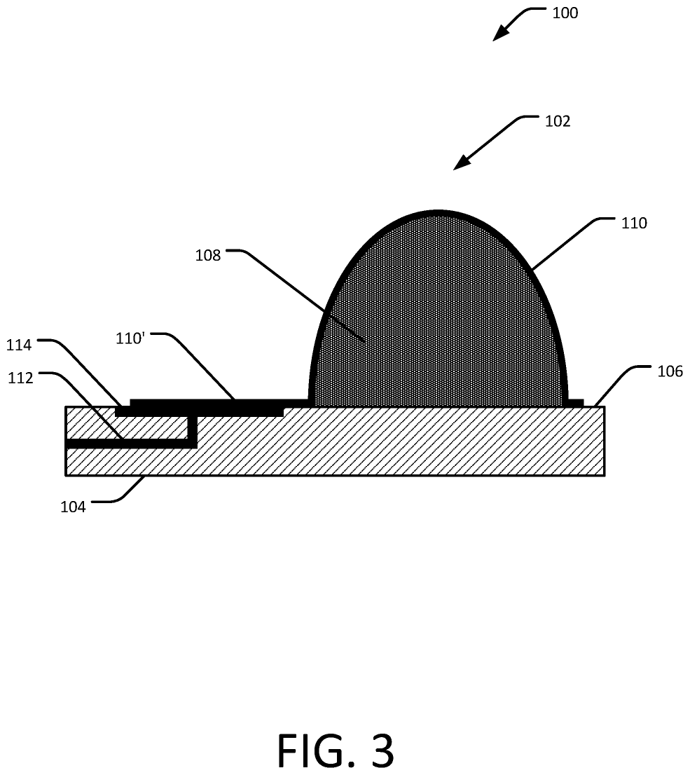

FIGS. 2 and 3 are alternate side cross-sectional views of the microelectronic component 100 of FIG. 1, in accordance with examples of the present disclosure. In both FIGS. 2 and 3, the conductive element 110 is electrically coupled to one or more conductive traces 112 on or in the substrate 104 via a conductive pad 114. For example, as shown in FIG. 2, the conductive pad 114 extends across a width of the bump 102 such that the conductive element 110 contacts the conductive pad 114 in two or more locations 202, 204 (e.g., along a circumference of the conductive element 110 at the surface 106 of the substrate 104). In another example, as shown in FIG. 3, the conductive pad 114 is located adjacent to the bump 102 and the conductive element 110 extends across the surface 106 of the substrate 104 over and in electrical contact with the conductive pad 114, as indicated at 110′. Other configurations and arrangements of the conductive element 110 and the conductive pad 114 will be apparent in light of the present disclosure.

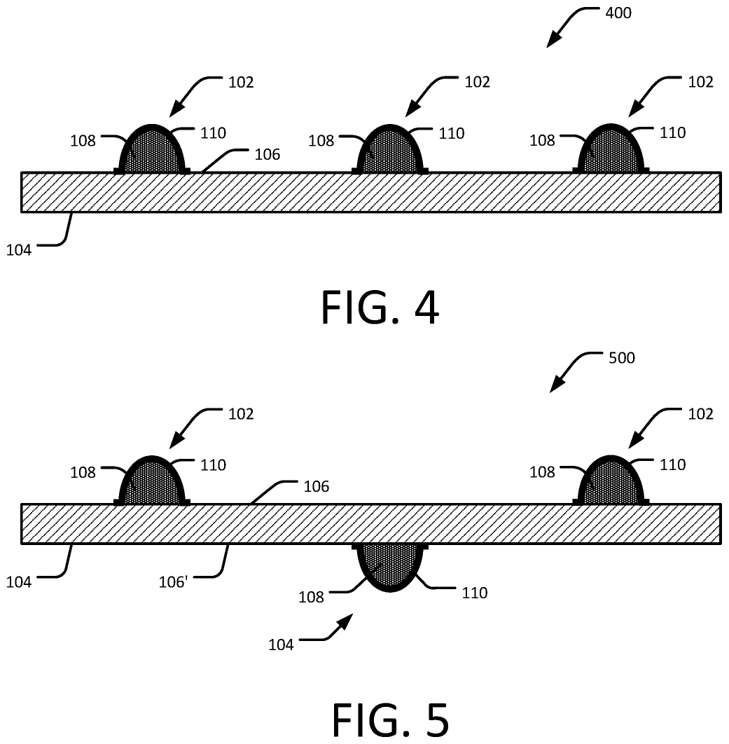

FIG. 4 is a side cross-sectional view of a microelectronic component 400 having multiple bumps 102 along the surface 106 of the substrate 104, in accordance with an example of the present disclosure. In this example, all of the bumps 102 are located on the same surface 106 of the substrate 104. It will be appreciated that there can be any number of such bumps 102 and the position and arrangement of the bumps 102 can be such that they correspond to the position and arrangement of the pads 114, such as shown in FIGS. 2 and 3.

FIG. 5 is a side cross-sectional view of a microelectronic component 500 having multiple bumps 102 along multiple surfaces 106, 106′ of the substrate 104, in accordance with an example of the present disclosure. In this example, at least one of the bumps 102 is located on one surface 106 of the substrate 104 and at least one of the bumps 102 is located on another, different surface 106′ of the substrate 104 (e.g., where surfaces 106 and 106′ are opposing surfaces). It will be appreciated that there can be any number of such bumps 102 and the position and arrangement of the bumps 102 can be such that they correspond to the position and arrangement of the pads 114, such as shown in FIGS. 2 and 3.

### Example Use Case

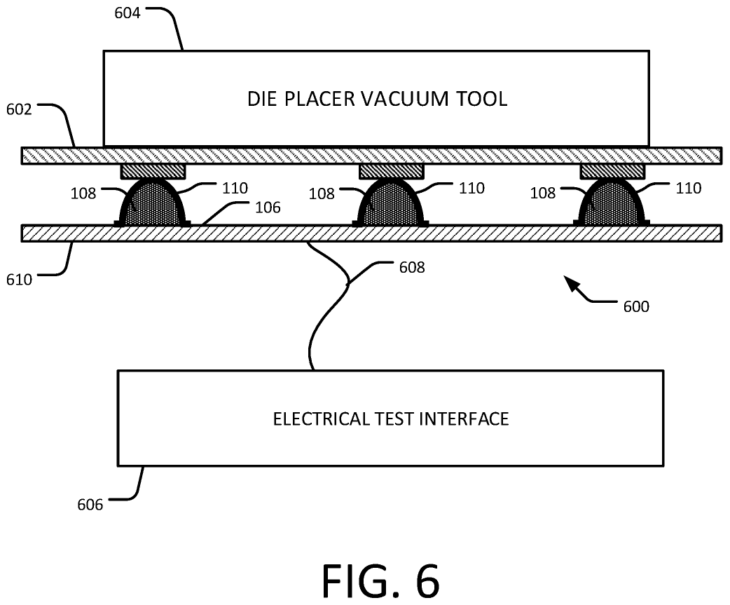

FIG. 6 is a block diagram showing a use case for a microelectronic component 600, in accordance with an example of the present disclosure. The microelectronic component can include, for example, any one or more of the microelectronic components 100, 400, 500 described herein. A probe card 610 can be brought into contact with the bumps 102 of the unit under test 602 either by moving the probe card 610 to the unit under test 602 using, for example, a die placer vacuum tool 604, while keeping the microelectronic component 600 stationary (similar to wafer probing techniques), or by moving the unit under test 602 to the probe card 610 while keeping the probe card 610 stationary (similar to pick and place techniques). In some examples, an electrical test interface 606 can be operatively connected to the unit under test 602 via an electrical cable 608. Once the probe card 610 is in contact with the microelectronic component 600, the electrical test interface 606 can activate the microelectronic component 600 for testing the operation of the microelectronic component 600 via the probe card 610.

### Fabrication

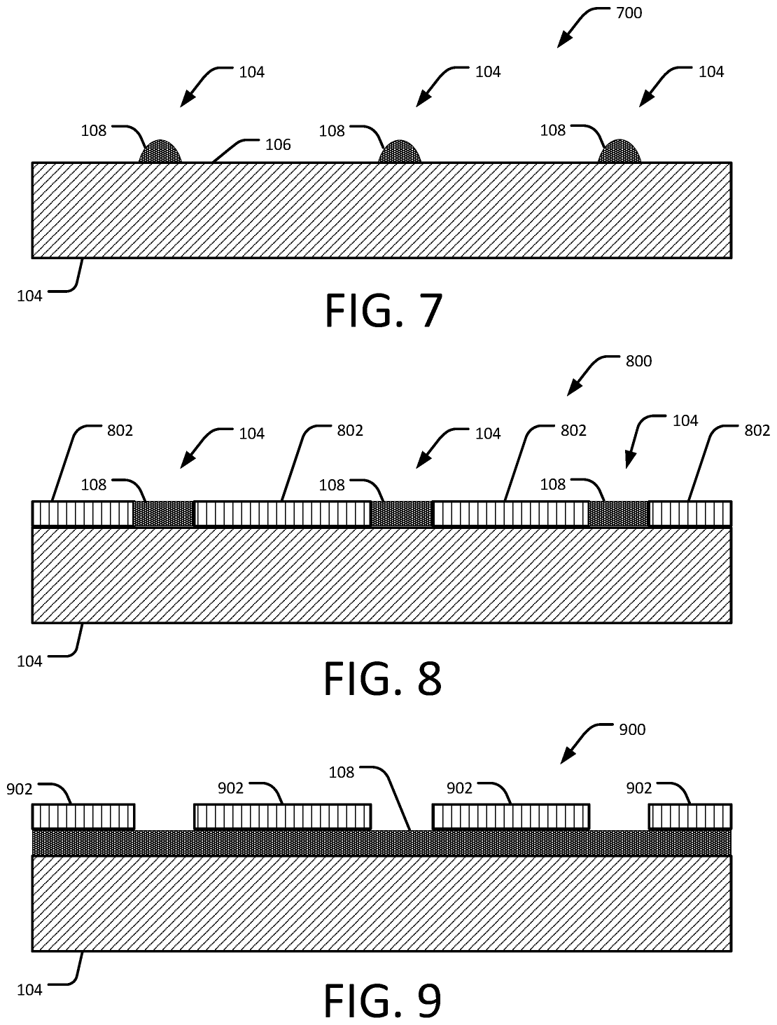

FIG. 7 is side cross-sectional view of a microelectronic component fabrication process 700 using deposition, in accordance with an example of the present disclosure. In FIG. 7, the resilient material 108 is time/pressure dispensed on the surface 106 of the substrate 104 to form domes or other shapes primarily with a positive curvature. The deposition can be performed using, for example, a computer numerical control (CNC) type machine configured to dispense the resilient material 108 onto the substrate 104. Examples of such dispense machines include time-pressure, auger, inkjet, or aerosol jet. Time-pressure or auger can be used, for instance, to fabricate relatively large bumps as they are typically set up for larger dispense dot sizes. Inkjet or aerosol jet can be used, for instance, to fabricate relatively small bumps as the dispense volume tends to be low and highly controllable.

FIG. 8 is side cross-sectional view of a microelectronic component fabrication process 800 using screening, in accordance with an example of the present disclosure. In FIG. 8, the resilient material 108 is screened on the surface 106 of the substrate 104. The screening can utilize a stencil 802, such as laser cut stainless steel or electroformed nickel, to screen print the resilient material 108 in specific locations on the substrate 104. Screening can be a quicker process than dispensing the resilient material 108, such described with respect to FIG. 7, since several or all of the bumps can be screen printed at the same time.

FIG. 9 is side cross-sectional view of a microelectronic component fabrication process 900 using microlithography, in accordance with an example of the present disclosure. Microlithography can utilize a polymer spin-on and developing process to form the bumps. In FIG. 9, the resilient material 108 is fabricated on the surface 106 of the substrate 104 using a microlithography process with a photo-tool or photomask 902 over the resilient material 108. Subsequently, the conductive element 110 (not shown in FIG. 9) can be applied onto the resilient material 108 using, for example, a physical vapor deposition (PVD), sputtering, chemical vapor deposition (CVD), or additive manufacturing technique. In some example cases, the conductive element 110 may be conformal, such that it has a relatively consistent thickness, as described above. Microlithography can permit fabrication of very small bumps due to higher resolution of the lithography masks.

It will be appreciated that the disclosed fabrication techniques can be selected based on the design (e.g., the size and scale of the bumps, the materials used, etc.), and that other fabrications techniques, such as three-dimensional printing or other additive manufacturing techniques, can be used to achieve the same or similar structures.

### Example Methodologies

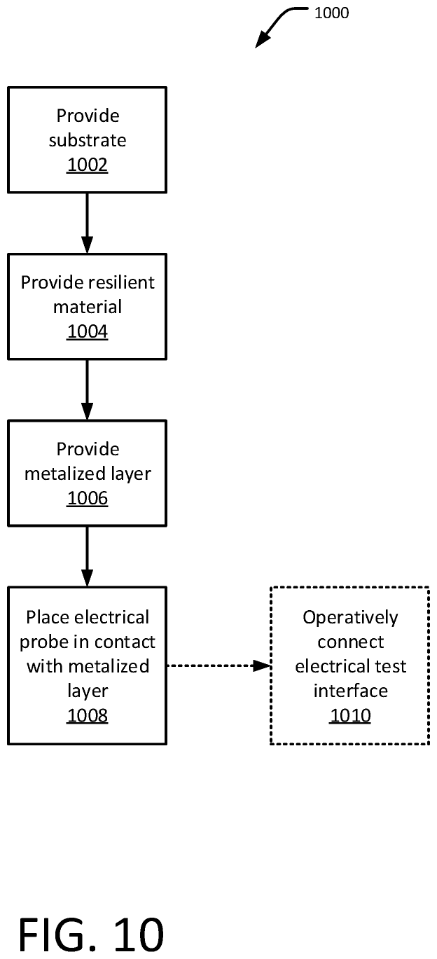

FIG. 10 is a flow diagram of an example methodology for testing a microelectronic component, according to an example of the present disclosure. The microelectronic component can include, for example, the microelectronic components variously described with respect to FIGS. 1-9. The methodology 1000 includes providing 1002 a substrate having at least one conductive pad; providing 1004 a resilient material on the substrate; providing 1006 a conductive element on or in the resilient material; and placing 1008 at least one electrical probe in contact with the conductive element. The conductive element can be in electrical communication with the at least one conductive pad. The methodology 1000 can, in some examples, further include operatively connecting 1010 the at least one conductive pad to an electrical test interface via an electrical cable.

In some examples, the providing 1002 of the resilient material comprises depositing the resilient material on the substrate using a time/pressure dispensing process. In some examples, the providing 1002 of the resilient material comprises screen printing the resilient material on the substrate using a stencil. In some examples, the providing 1002 of the resilient material comprises printing the resilient material on the substrate microlithography process using a protective film or mask. In some examples, the resilient material includes a compressible polymer, such as described with respect to FIGS. 1-9.

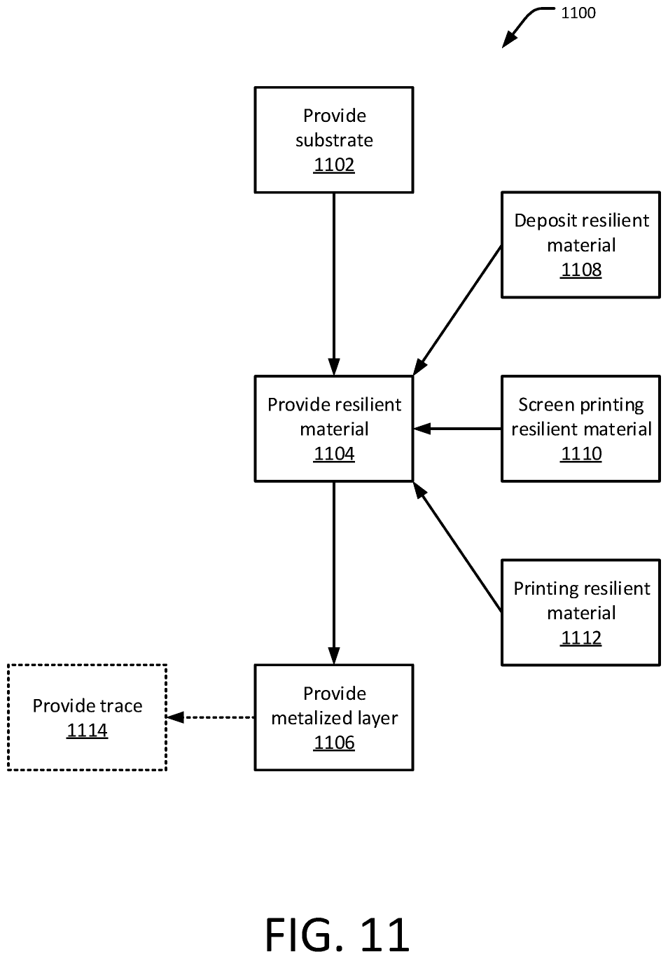

FIG. 11 is a flow diagram of a methodology 1100 for fabricating a microelectronic component, in accordance with an example of the present disclosure. The microelectronic component can include, for example, the microelectronic components variously described with respect to FIGS. 1-9. The methodology 1100 includes providing 1102 a substrate having at least one conductive pad; providing 1104 a resilient material on the substrate; and providing 1106 a conductive element on or in the resilient material, the conductive element being in electrical communication with the at least one conductive pad.

In some examples, the providing 1102 of the resilient material comprises depositing 1108 the resilient material on the substrate using a time/pressure dispensing process. In some examples, the providing 1102 of the resilient material comprises screen printing 1110 the resilient material on the substrate using a stencil. In some examples, the providing 1102 of the resilient material comprises printing 1112 the resilient material on the substrate using microlithography process with a protective film or mask. In some examples, the resilient material includes a compressible polymer, such as described with respect to FIGS. 1-9.

In some examples, the methodology 1100 further includes providing 1114 at least one trace on the substrate, the trace being electrically coupled to the at least one conductive pad.

### Further Examples

The following examples pertain to further examples, from which numerous permutations and configurations will be apparent.

Example 1 provides a microelectronic component comprising a substrate having at least one conductive pad; a resilient material on the substrate; and a conductive element on or in the resilient material, the conductive element being coupled to the at least one conductive pad.

Example 2 includes the subject matter of Example 1, wherein the resilient material includes a compressible polymer.

Example 3 includes the subject matter of any one of Examples 1 and 2, further comprising at least one conductive trace on the substrate, the trace being coupled to the at least one conductive pad.

Example 4 includes the subject matter of any one of Examples 1-3, wherein the conductive element is accessible to at least one test probe.

Example 5 includes the subject matter of Example 4, wherein the resilient material compresses into a deformed shape in response to a contact between the at least one test probe contact and the conductive element.

Example 6 includes the subject matter of Example 5, wherein the resilient material is configured to return from the deformed shape to an undeformed shape in response to a withdrawal of the at least one test probe from the conductive element.

Example 7 includes the subject matter of any one of Examples 1-6, wherein the conductive element includes a conformal layer.

Example 8 provides a method of fabricating a microelectronic component, the method comprising providing a substrate having at least one conductive pad; providing a resilient material on the substrate; and providing a conductive element on or in the resilient material, the conductive element being in electrical contact with the at least one conductive pad.

Example 9 includes the subject matter of Example 8, wherein the providing the conductive element includes depositing a metalized layer on the resilient material.

Example 10 includes the subject matter of any one of Examples 8 and 9, wherein the providing of the resilient material comprises depositing the resilient material on the substrate using a time/pressure dispensing process.

Example 11 includes the subject matter of any one of Examples 8-10, wherein the providing of the resilient material comprises screen printing the resilient material on the substrate using a stencil.

Example 12 includes the subject matter of any one of Examples 8-11, wherein the providing of the resilient material comprises printing the resilient material on the substrate using a microlithography process.

Example 13 includes the subject matter of any one of Examples 8-12, wherein the resilient material includes a compressible polymer.

Example 14 includes the subject matter of any one of Examples 8-13, further comprising providing at least one conductive trace on the substrate, the trace being electrically coupled to the at least one conductive pad.

Example 15 includes the subject matter of any one of Examples 8-14, wherein the resilient material compresses into a deformed shape in response to a test probe contacting the conductive element, and wherein the resilient material is configured to return from the deformed shape to an undeformed shape subsequent to a removal of the conductive element from contacting the test probe.

Example 16 provides a method of testing a microelectronic component, the method comprising providing a substrate having at least one conductive pad; providing a resilient material on the substrate; providing a conductive element on or in the resilient material, conductive element being in electrical contact with the at least one conductive pad; and placing at least one test probe in contact with the conductive element.

Example 17 includes the subject matter of Example 16, further comprising operatively connecting the at least one conductive pad to a test interface via an electrical cable.

Example 18 includes the subject matter of any one of Examples 16 and 17, wherein the providing of the resilient material comprises depositing the resilient material on the substrate using a time/pressure dispensing process.

Example 19 includes the subject matter of any one of Examples 16 and 17, wherein the providing of the resilient material comprises screen printing the resilient material on the substrate.

Example 20 includes the subject matter of any one of Examples 16 and 17, wherein the providing of the resilient material comprises printing the resilient material on the substrate using a microlithography process.

Example 21 provides a method of testing a microelectronic component, the method comprising placing at least one test probe in contact with a conductive element, the conductive element being in electrical contact with at least one conductive pad on a substrate, the conductive element being on or in a resilient material on the substrate.

Example 22 includes the subject matter of Example 21, further comprising operatively connecting the at least one conductive pad to a test interface via an electrical cable.

Example 23 includes the subject matter of any one of Examples 21 and 22, wherein the resilient material is deposited on the substrate using a time/pressure dispensing process.

Example 24 includes the subject matter of any one of Examples 21 and 22, wherein the resilient material is screen printed on the substrate.

Example 25 includes the subject matter of any one of Examples 21 and 22, wherein the resilient material is printed on the substrate using a microlithography process.

Numerous specific details have been set forth herein to provide a thorough understanding of the examples. It will be understood that other examples may be practiced without these specific details, or otherwise with a different set of details. It will be further appreciated that the specific structural and functional details disclosed herein are representative of examples and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims. Furthermore, examples described herein may include other elements and components not specifically described, such as electrical connections, signal transmitters and receivers, processors, or other suitable components for operation of the modular antenna.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and examples have been described herein. The features, aspects, and examples are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A microelectronic component comprising:
a substrate having at least one conductive pad;
a resilient material on the substrate; and
a conductive element on or in the resilient material, the conductive element being coupled to the at least one conductive pad.

2. The microelectronic component of claim 1, wherein the resilient material includes a compressible polymer.

3. The microelectronic component of claim 1, further comprising at least one conductive trace on the substrate, the at least one conductive trace being coupled to the at least one conductive pad.

4. The microelectronic component of claim 1, wherein the conductive element is accessible to at least one test probe.

5. The microelectronic component of claim 4, wherein the resilient material compresses into a deformed shape in response to a contact between the at least one test probe contact and the conductive element.

6. The microelectronic component of claim 5, wherein the resilient material is configured to return from the deformed shape to an undeformed shape in response to a withdrawal of the at least one test probe from the conductive element.

7. The microelectronic component of claim 1, wherein the conductive element includes a conformal layer.

8. A method of fabricating a microelectronic component, the method comprising:
providing a substrate having at least one conductive pad;
providing a resilient material on the substrate; and
providing a conductive element on or in the resilient material, the conductive element being in electrical contact with the at least one conductive pad.

9. The method of claim 8, wherein the providing the conductive element includes depositing a metalized layer on the resilient material.

10. The method of claim 8, wherein the providing of the resilient material comprises depositing the resilient material on the substrate using a time/pressure dispensing process.

11. The method of claim 8, wherein the providing of the resilient material comprises screen printing the resilient material on the substrate using a stencil.

12. The method of claim 8, wherein the providing of the resilient material comprises printing the resilient material on the substrate using a microlithography process.

13. The method of claim 8, wherein the resilient material includes a compressible polymer.

14. The method of claim 8, further comprising providing at least one conductive trace on the substrate, the at least one conductive trace being electrically coupled to the at least one conductive pad.

15. The method of claim 8, wherein the resilient material compresses into a deformed shape in response to a test probe contacting the conductive element, and wherein the resilient material is configured to return from the deformed shape to an undeformed shape subsequent to a removal of the conductive element from contacting the test probe.

16. A method of testing a microelectronic component, the method comprising:
placing at least one test probe in contact with a conductive element,
the conductive element being in electrical contact with at least one conductive pad on a substrate, the conductive element being on or in a resilient material on the substrate.

17. The method of claim 16, further comprising operatively connecting the at least one conductive pad to a test interface via an electrical cable.

18. The method of claim 16, wherein the resilient material is deposited on the substrate using a time/pressure dispensing process.

19. The method of claim 16, wherein the resilient material is screen printed on the substrate.

20. The method of claim 16, wherein the resilient material is printed on the substrate using a microlithography process.
